(19) United States
(12) Patent Application Publication
(10) Pub. No.: US 2017/0117466 A1
(43) Pub. Date: Apr. 27, 2017

(54) Resistive Random Access Memory

(71) Applicant: NATIONAL SUN YAT-SEN UNIVERSITY, Kaohsiung City (TW)

(72) Inventors: Ting-Chang Chang, Kaohsiung City (TW); Kuan-Chang Chang, Kaohsiung City (TW); Tsung-Ming Tsai, Kaohsiung City (TW); Tian-Jian Chu, Kaohsiung City (TW); Chih-Hung Pan, Kaohsiung City (TW)

(21) Appl. No.: 14/957,674

(22) Filed: Dec. 3, 2015

(30) Foreign Application Priority Data
Oct. 26, 2015 (TW) 104135116

(51) Int. Cl. H01L 45/00

(52) U.S. Cl. CPC H01L 45/124; H01L 45/085; H01L 45/1253; H01L 45/146

(57) ABSTRACT

A resistive random access memory overcomes the difficulty in reducing the forming voltage thereof. The resistive random access memory includes a first electrode layer, a separating portion, a lateral wall portion, an oxygen-containing rheostatic layer and a second electrode layer. The separating portion is arranged on the first electrode layer and forms a through-hole. The first electrode layer is exposed via the through-hole. The lateral wall portion is annularly arranged on an inner periphery of the separating portion defining the through-hole. The lateral wall portion is connected to the first electrode layer and includes a first dielectric. The oxygen-containing rheostatic layer covers the first electrode layer, the separating portion and the lateral wall portion. The oxygen-containing rheostatic layer includes a second dielectric smaller than the first dielectric. The second electrode layer is arranged on the oxygen-containing rheostatic layer. In this structure, the difficulty can be effectively overcome.

### CROSS REFERENCE TO RELATED APPLICATIONS

The application claims the benefit of Taiwan application serial No. 104135116, filed on Oct. 26, 2015, and the subject matter of which is incorporated herein by reference.

### BACKGROUND OF THE INVENTION

1. Field of the Invention

The present disclosure generally relates to a resistive random access memory and, more particularly, to a resistive random access memory having a plurality of dielectrics with different dielectric constants.

2. Description of the Related Art

Memory devices have been widely used in electronic products. Among various types of memory devices, the resistive random access memory has the advantages such as low operational voltage, fast retrieving speed and high compactness. Thus, the resistive random access memory has the potential to replace the conventional flash memory and dynamic random access memory, and may become the mainstream of the memory devices in the next generation.

FIG. 1 is a cross sectional view of a conventional resistive random access memory 9. The resistive random access memory 9 includes a lower electrode 91, a first dielectric layer 92, a second dielectric layer 93 and an upper electrode 94. The lower electrode 91 is arranged on the first dielectric layer 92. The first dielectric layer 92 forms a through-hole 921. The second dielectric layer 93 is arranged on the surfaces of the lower electrode 91 and the first dielectric layer 92. The second dielectric layer 93 forms a dented portion 931. The upper electrode 94 extends out of the dented portion 931 from the interior of the dented portion 931 and forms a notch 941. The first dielectric layer 92 has a dielectric constant (such as K=3.9) which is usually much smaller than the dielectric constant of the second dielectric layer 93 (such as K=25). When power is applied between the lower electrode 91 and the upper electrode 94, the second dielectric layer 93 may be switched between a low resistance state (LRS) and a high resistance state (HRS). One embodiment of such a conventional resistive random access memory may be seen in “Characteristics and Mechanisms of Silicon-Oxide-Based Resistance Random Access Memory” as published in IEEE ELECTRON DEVICE LETTERS, VOL. 34, NO. 3 on March 2013.

Since the dielectric constant of the first dielectric layer 92 is usually smaller than that of the second dielectric layer 93, the reduction of size of the through-hole 921 usually increases the average value of the forming voltage. However, as the size of the through-hole 921 increases from 1 μm to 4 μm, the average value of the forming voltage is still around 14-16V. Therefore, the forming voltage of the conventional resistive random access memory 9 cannot be reduced by changing the size of the through-hole 921. If the forming voltage of the conventional resistive random access memory 9 is too large, some undesired effects will take place when the resistive random access memory 9 operates on an integrated circuit.

In light of this, it is necessary to improve the conventional resistive random access memory 9.

### SUMMARY OF THE INVENTION

It is therefore the objective of this disclosure to provide a resistive random access memory with a smaller forming voltage.

In an embodiment of the disclosure, a resistive random access memory including a first electrode layer, a separating portion, a lateral wall portion, an oxygen-containing rheostatic layer and a second electrode layer is disclosed. The separating portion is arranged on the first electrode layer and forms a through-hole. The first electrode layer is exposed via the through-hole. The lateral wall portion is annularly arranged on an inner periphery of the separating portion defining the through-hole. The lateral wall portion is connected to the first electrode layer and includes a first dielectric. The oxygen-containing rheostatic layer covers the first electrode layer, the separating portion and the lateral wall portion. The oxygen-containing rheostatic layer includes a second dielectric having a dielectric constant smaller than a dielectric constant of the first dielectric of the lateral wall portion. The second electrode layer is arranged on the oxygen-containing rheostatic layer.

In a form shown, the first dielectric of the lateral wall portion is selected from one of hafnium dioxide, silicon nitride or silicon dioxide.

In the form shown, the first electrode layer includes a mounting face, the separating portion includes a first face and a second face opposite to the first face, and the first face is coupled with the mounting face of the first electrode layer. The through-hole extends through the first and second faces, such that the mounting face of the first electrode layer is exposed via the through-hole.

In the form shown, the oxygen-containing rheostatic layer extends from the mounting face of the first electrode layer to the second face of the separating portion through the lateral wall portion.

In the form shown, the second dielectric of the oxygen-containing rheostatic layer is a composition of hafnium dioxide and silicon dioxide.

In the form shown, the hafnium dioxide has a mole ratio of 1-10% in the composition.

In the form shown, the separating portion includes a third dielectric having a dielectric constant smaller than a dielectric constant of the second dielectric of the oxygen-containing rheostatic layer.

In the form shown, the third dielectric includes silicon dioxide.

In the form shown, the oxygen-containing rheostatic layer forms a recess portion which is located in the through-hole of the separating portion.

In the form shown, the second electrode layer extends out of the recess portion from an interior of the recess portion.

In the form shown, the second electrode layer forms a hole which is located in the recess portion of the oxygen-containing rheostatic layer.

In the above resistive random access memory, since the first dielectric of the lateral wall portion is larger than the second dielectric of the oxygen-containing rheostatic layer, the electric field will concentrate in the oxygen-containing rheostatic layer which has a smaller dielectric constant. The required breakdown voltage of the resistive random access memory does not change, advantageously lowing the forming voltage of the resistive random access memory. In addition, when the size of the resistive random access memory of the embodiment of the disclosure is reduced, the forming voltage does not increase as the size of the through-hole decreases. As such, the forming voltage is more stable, as opposed to the conventional resistive random access memory where the forming voltage continuously increases as the size of the through-hole decreases. Another advantage is that the power consumption is smaller as compared with the large power consumption of the conventional resistive random access memory.

### BRIEF DESCRIPTION OF THE DRAWINGS

The present disclosure will become more fully understood from the detailed description given hereinafter and the accompanying drawings which are given by way of illustration only, and thus are not limitative of the present disclosure, and wherein:

FIG. 1 is a cross sectional view of a conventional resistive random access memory.

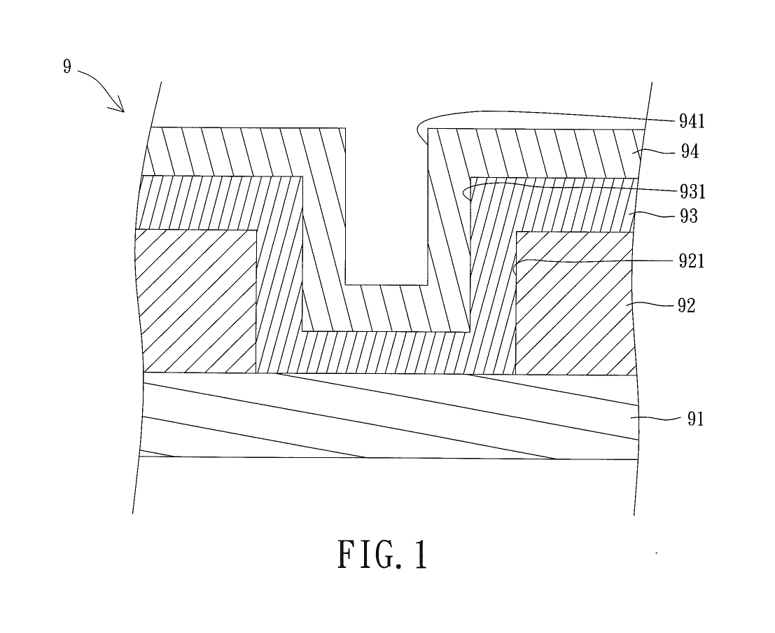

FIG. 2 shows a relation chart between the forming voltage and the size of the through-hole of the conventional resistive random access memory.

FIG. 3 is a cross sectional view of a resistive random access memory according to an embodiment of the invention.

FIG. 4 shows a relation chart between the forming voltage and the size of the through-hole of the resistive random access memory according to the embodiment of the invention.

In the various figures of the drawings, the same numerals designate the same or similar parts. Furthermore, when the terms “first”, “second”, “third”, “fourth”, “inner”, “outer”, “top”, “bottom”, “front”, “rear” and similar terms are used hereinafter, it should be understood that these terms have reference only to the structure shown in the drawings as it would appear to a person viewing the drawings, and are utilized only to facilitate describing the disclosure.

### DETAILED DESCRIPTION OF THE INVENTION

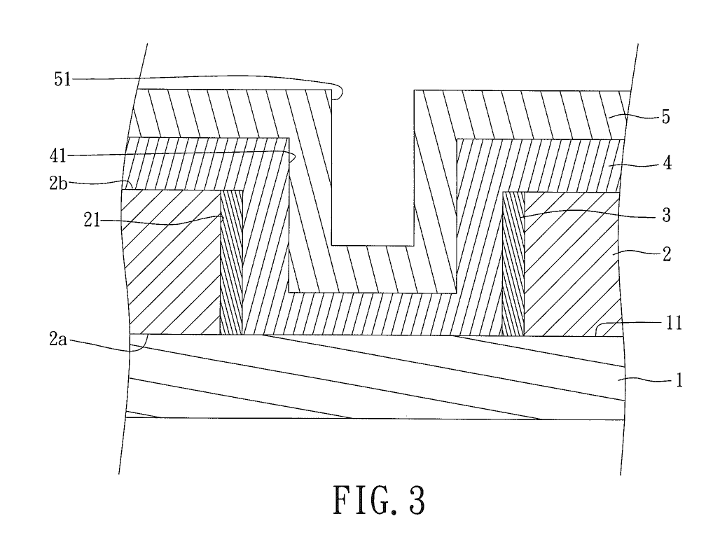

FIG. 3 is a cross sectional view of a resistive random access memory according to an embodiment of the disclosure. In the embodiment, the resistive random access memory may include a first electrode layer 1, a separating portion 2, a lateral wall portion 3, an oxygen-containing rheostatic layer 4 and a second electrode layer 5. The separating portion 2 may be arranged on the first electrode layer 1 and may include a through-hole 21. The first electrode layer 1 is exposed via the through-hole 21. The lateral wall portion 3 may be annularly arranged on an inner periphery of the separating portion 2 defining the through-hole 21. The lateral wall portion 3 is connected to the first electrode layer 1 and may include a first dielectric. The oxygen-containing rheostatic layer 4 may cover the first electrode layer 1, the separating portion 2 and the lateral wall portion 3. The oxygen-containing rheostatic layer 4 may include a second dielectric having a dielectric constant smaller than that of the first dielectric of the lateral wall portion 3. The second electrode layer 5 may be arranged on the oxygen-containing rheostatic layer 4. The resistive random access memory according to the embodiment of the invention will be discussed in detail below.

The first electrode layer 1 may be made of an electricity conducting material such as platinum or titanium nitride, for example. The first electrode layer 1 includes a mounting face 11 on which the separating portion 2, the lateral wall portion 3, the oxygen-containing rheostatic layer 4 and the second electrode layer 5 are arranged. The separating portion 2 may include a first face 2a and a second face 2b opposite to the first face 2a. The first face 2a may couple with the mounting face 11 of the first electrode layer 1. The through-hole 21 that extends through the first face 2a and the second face 2b may be formed by an etching process, such that the mounting face 11 of the first electrode layer 1 may be exposed via the through-hole 21. The separating portion 2 may include a third dielectric having a dielectric constant smaller than that of the second dielectric of the oxygen-containing rheostatic layer 4. The third dielectric may be silicon dioxide (SiO₂, K=3.9), but is not limited thereto.

The lateral wall portion 3 may be annularly arranged on the inner periphery of the separating portion 2 defining the through-hole 21. Specifically, the anisotropic etching technology may be performed such that some substance with a high dielectric constant can remain on the inner periphery of the separating portion 2. The lateral wall portion 3 includes one end connected to the mounting face 11 of the first electrode layer 1. The first dielectric of the lateral wall portion 3 may be a material having a dielectric constant (K value) larger than or equal to 3.9, such as hafnium dioxide (HfO₂, K=25), silicon nitride (Si₃N₄, K=7) or silicon dioxide (SiO₂, K=3.9), but is not limited thereto.

The second dielectric of the oxygen-containing rheostatic layer 4 may be a composition of hafnium dioxide (HfO₂) and silicon dioxide (SiO₂). The hafnium dioxide may have a mole ratio of 1-10% in the composition. The composition has a dielectric constant of 4.0-5.9, which is smaller than that of the first dielectric in order to concentrate the electric field in the oxygen-containing rheostatic layer 4. The oxygen-containing rheostatic layer 4 may extend from the mounting face 11 of the first electrode layer 1 to the second face 2b of the separating portion 2 through the lateral wall portion 3, and may form a recess portion 41 by an etching process. The recess portion 41 may be located in the through-hole 21 of the separating portion 2.

The second electrode layer 5 may be made of an electricity conducting material, such as indium tin oxide (ITO) or platinum. The second electrode layer 5 may extend out of the recess portion 41 from the interior of the recess portion 41, forming a hole 51. The hole 51 is located in the recess portion 41 of the oxygen-containing rheostatic layer 4. The shapes of the through-hole 21, the recess portion 41 and the hole 51 may be changed according to the requirements.

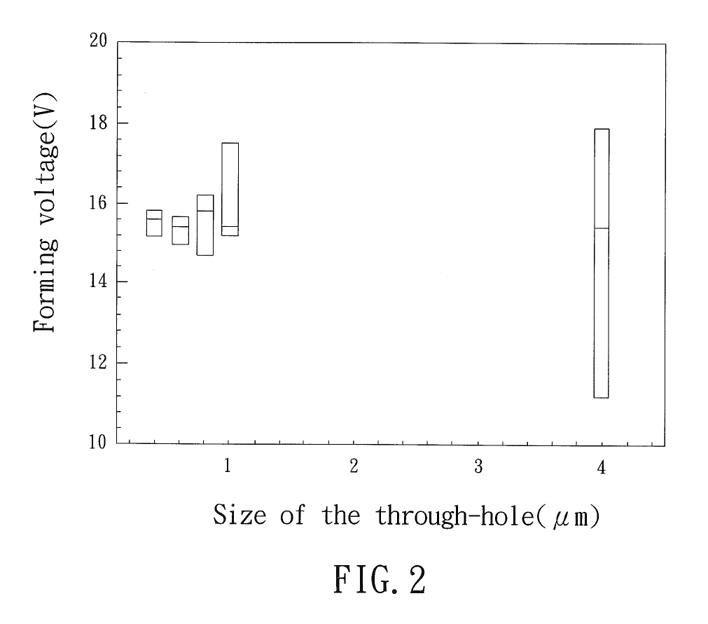

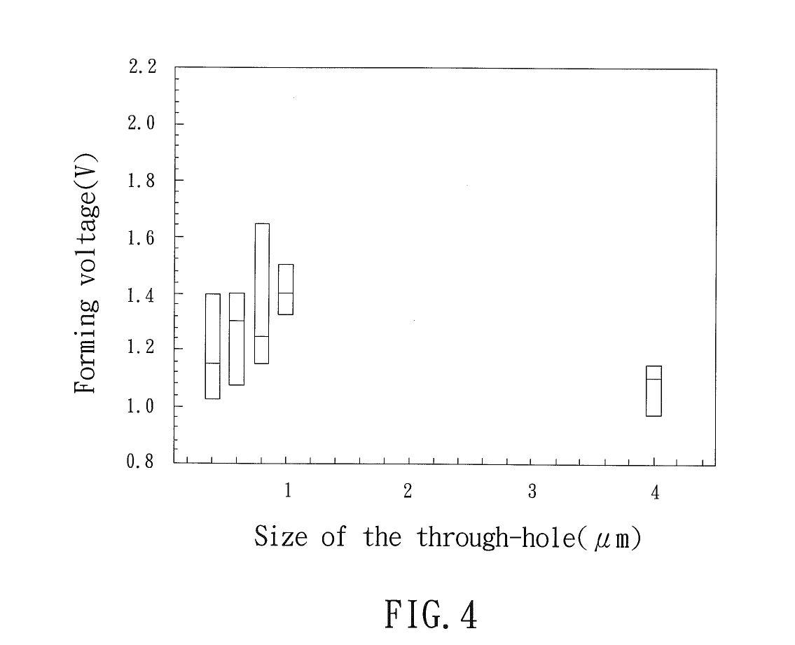

FIG. 4 shows a relation chart between the forming voltage and the size of the through-hole of the resistive random access memory according to the embodiment of the invention. The size of the through-hole is between 1-4 μm, and the average value of the forming voltage may be reduced to about 1.0-1.4V. As compared with the forming voltage of the conventional resistive random access memory (which is between 14-16V as shown in FIG. 2), the resistive random access memory according to the embodiment of the invention has a much smaller forming voltage, avoiding the undesired effects which take place when the resistive random access memory operates on an integrated circuit (such as large power consumption).

During the use of the resistive random access memory according to the embodiment of the disclosure, an electric field may be applied between the first electrode layer 1 and the second electrode layer 5. As such, a redox reaction can be triggered through the oxygen ions in the oxygen-containing rheostatic layer 4, switching the oxygen-containing rheostatic layer 4 between the high and low resistance states.

In the resistive random access memory according to the embodiment of the disclosure, the first dielectric of the lateral wall portion 3 is larger than the second dielectric of the oxygen-containing rheostatic layer 4. As such, the electric field will concentrate in the oxygen-containing rheostatic layer 4 which has a smaller dielectric constant (without being shared by the separating portion 2). Thus, the required breakdown voltage of the resistive random access memory will not change, advantageously lowing the forming voltage of the resistive random access memory.

Furthermore, when the size of the resistive random access memory is reduced (for example, the size of the through-hole 21 is reduced from 4 μm to 1 μm), the forming voltage of the resistive random access memory may remain 1.0-1.4V. The forming voltage does not increase as the size of the through-hole 21 decreases, advantageously providing a stable forming voltage. As compared with the conventional resistive random access memory whose forming voltage continuously increases as the size of the through-hole decrease, the resistive random access memory according to the embodiment of the disclosure does avoid the undesired effects which take place when the resistive random access memory operates on an integrated circuit (such as large power consumption).

Although the disclosure has been described in detail with reference to its presently preferable embodiments, it will be understood by one of ordinary skill in the art that various modifications can be made without departing from the spirit and the scope of the disclosure, as set forth in the appended claims.

1. (canceled)

2. The resistive random access memory as claimed in claim 6, wherein the first dielectric of the lateral wall portion is selected from one of hafnium dioxide and silicon nitride.

3. The resistive random access memory as claimed in claim 6, wherein the first electrode layer comprises a mounting face, wherein the separating portion comprises a first face and a second face opposite to the first face, wherein the first face is coupled with the mounting face of the first electrode layer, and wherein the through-hole extends through the first and second faces, such that the mounting face of the first electrode layer is exposed via the through-hole.

4. The resistive random access memory as claimed in claim 3, wherein the oxygen-containing rheostatic layer extends from the mounting face of the first electrode layer to the second face of the separating portion through the lateral wall portion.

5. (canceled)

6. A resistive random access memory comprising:
a first electrode layer made of platinum or titanium nitride;
a separating portion arranged on the first electrode layer and forming a through-hole, wherein the first electrode layer is exposed via the through-hole;
a lateral wall portion annularly arranged on an inner periphery of the separating portion, wherein the inner periphery defines the through-hole, wherein the lateral wall portion is connected to the first electrode layer and comprises a first dielectric;
an oxygen-containing rheostatic layer covering the first electrode layer, the separating portion and the lateral wall portion, wherein the oxygen-containing rheostatic layer comprises a second dielectric having a dielectric constant smaller than a dielectric constant of the first dielectric of the lateral wall portion, wherein the second dielectric of the oxygen-containing rheostatic layer is a composition of hafnium dioxide and silicon dioxide; and
a second electrode layer arranged on the oxygen-containing rheostatic layer and made of indium tin oxide or platinum, wherein the hafnium dioxide has a mole ratio of 1-10% in the composition.

7. The resistive random access memory as claimed in claim 6, wherein the separating portion comprises a third dielectric having a dielectric constant smaller than a dielectric constant of the second dielectric of the oxygen-containing rheostatic layer.

8. The resistive random access memory as claimed in claim 7, wherein the third dielectric comprises silicon dioxide.

9. The resistive random access memory as claimed in claim 6, wherein the oxygen-containing rheostatic layer forms a recess portion located in the through-hole of the separating portion.

10. The resistive random access memory as claimed in claim 9, wherein the second electrode layer extends out of the recess portion from an interior of the recess portion.

11. The resistive random access memory as claimed in claim 9, wherein the second electrode layer forms a hole which is located in the recess portion of the oxygen-containing rheostatic layer.
